(19) United States
(12) Patent Application Publication
(10) Pub. No.: US 2025/0256494 A1
(43) Pub. Date: Aug. 14, 2025

(54) A METHOD FOR MANUFACTURING A PAPERBOARD BASED PACKAGING LAMINATE

(71) Applicant: Stora Enso OYJ, Helsinki (FI)

(72) Inventors: Magnus Ekberg, Fors (SE); Kaj Backfolk, Lappeenranta (FI)

(73) Assignee: Stora Enso OYJ, Helsinki (FI)

(21) Appl. No.: 18/992,256

(22) PCT Filed: Jul. 6, 2023
(86) PCT No.: PCT/IB2023/057000

§ 371 Date: Jan. 8, 2025

(30) Foreign Application Priority Data
Jul. 11, 2022 (SE) 2230235-0

(51) Int. Cl. B32B 27/10; B32B 5/02; B32B 7/12; B32B 27/32; B32B 37/12

(52) U.S. Cl. CPC B32B 27/10; B32B 5/02; B32B 7/12; B32B 27/32; B32B 37/1284; B32B 2255/12; B32B 2307/72; B32B 2307/7244; B32B 2307/7246; B32B 2307/7376; B32B 2439/40

(57) ABSTRACT

The present invention relates to method for manufacturing a paperboard based packaging laminate, said method comprising: a) providing a paperboard base layer. b) providing a vacuum coated film layer. c) applying an adhesive composition to the paperboard base layer and/or the vacuum coated film layer. d) laminating a surface of the paperboard base layer to a surface of the vacuum coated film layer using the adhesive composition in a press nip. such that the adhesive composition forms an adhesive tie layer between the paperboard base layer and the vacuum coated film layer, to form a laminate. wherein the position of the press nip is adjusted in a direction perpendicular to the laminated surfaces during the lamination to compensate for changes in curl in the formed laminate.

### TECHNICAL FIELD

The present disclosure relates to methods for manufacturing paperboard based packaging materials. More specifically, the present disclosure relates to the manufacture of paperboard based packaging laminates comprising a vacuum coated film layer.

### BACKGROUND

Coating of paperboard with plastics is often employed to combine the mechanical properties of the paperboard with the barrier and sealing properties of a plastic film. Paperboard provided with even a relatively small amount of a suitable plastic material can provide the properties needed to make the paperboard suitable for many demanding applications, for example as liquid or food packaging board. In liquid or food packaging board, polyolefin coatings are frequently used as liquid barrier layers, heat sealing layers and adhesives. However, the recycling of such polymer coated board is difficult since it is difficult to separate the polymers from the fibers.

Also, in many cases the water vapor barrier properties of the polymer coated paperboard are still insufficient unless the coating layers are thick or combinations of different polymer coating layers are used. Therefore, in order to ensure high water vapor barrier properties, the polymer coated paperboard is often combined with one or more layers of aluminum foil. However, the addition of polymer and aluminum foil add significant costs and the combination of polymer coating layers and aluminum foils makes recycling of the materials more difficult. Also, due to its high carbon footprint there is a wish to replace aluminum foils in paperboard based packaging materials.

Aseptic packaging for long shelf-life products such as milk and juices are usually made from liquid or food packaging board comprising a multilayer paperboard based substrate, an outermost heat-sealable polyolefin (e.g. polyethylene, PE) layer and innermost layers of polyolefin and aluminum. The aluminum foil layer, needed to provide water vapor and oxygen barrier properties, is usually incorporated between layers of polyethylene to provide the following structure: PE/paperboard/PE/aluminum/PE.

In the prior art, attempts have been made to replace the aluminum foil with more environmentally friendly and/or easier to recycle solutions, but so far with no real success. For example, microfibrillated cellulose (MFC) films and coatings have been developed, in which fibrillated cellulosic fibers and microfibrils have been dispersed e.g. in water and thereafter re-organized and rebonded together to form a dense film or coating with excellent gas barrier properties. Unfortunately, the water vapor and gas barrier properties of such MFC films tend to deteriorate at high humidity.

One solution discussed in the prior art is to deposit a thin vacuum coating layer directly onto a substrate using for example chemical or physical vapor deposition techniques. The thin vacuum coating layer may for example comprise a thin layer of aluminum, Al₂O₃, AlOx, or SiOx. A problem with these deposition techniques is that the coating process takes place under vacuum, which means that the substrate needs to be degassed. For paperboard, and especially thicker low-density paperboards, this means that the process adds costs, but the degassing also means that the substrate is dried to a very low moisture content. This drying and the subsequent remoisturizing to ambient moisture levels changes the mechanical properties of the board. The drying will not only increase the cracking tendency and post-convertability of the board but there is also a significant risk of cracking of the thin and sensitive vacuum coating layer as the board is remoisturized.

It has also been proposed to replace the aluminum foil with metallized polymer or cellulose based films, such as metallized polyethylene or polypropylene films, which are laminated to the paperboard-based substrate by an adhesive tie layer. The adhesive tie layer may for example be applied in melt form by extrusion coating or in the form of a water-based solution or dispersion using liquid coating methods.

A problem with metallized films is that the thin metallization layer is sensitive to movements in the substrate film on which the metallization layer is applied and movements in the finished laminate, which may cause cracks or pinholes in the metallization.

High temperatures applied lamination processes when a tie layer or heat-sealing layer is extruded might lead to the metallized polymer or cellulose based film being stretched (expanded) and then shrunk when cooled, which can cause pin holes and cracks in the thin and sensitive metallization layer affecting the gas barrier properties of the laminate negatively.

A problem associated with the use of water-based adhesive to laminate the metallized film to the paperboard is that wetting of the paperboard based substrate may cause curling of the web to occur, due to the high amount of water applied with the adhesive.

Thus, there remains a need for improved solutions to replace the combination of plastic films and aluminum foils in paperboard based packaging materials, while maintaining acceptable liquid and oxygen barrier properties. At the same time, there is a need to replace the combination of plastic films and aluminum foils with alternatives that facilitate re-pulping and recycling of the used packaging materials.

### DESCRIPTION OF THE INVENTION

It is an object of the present disclosure to provide an alternative method for manufacturing a paperboard based packaging laminate, such as a liquid or food packaging board, which provides good water vapor barrier properties even at higher relative humidity and temperature.

It is a further object of the present disclosure, to provide an alternative method for manufacturing a paperboard based packaging laminate comprising a vacuum coated film layer, which overcomes at least some of the problems, such as curling of the web and/or pinhole formation or cracking of the thin and sensitive vacuum coating layers associated with prior art manufacturing methods.

It is a further object of the present disclosure to provide an alternative method for manufacturing a paperboard based packaging laminate, which has an water vapor transmission rate (WVTR), measured according to the standard ASTM F1249-20 at 50% relative humidity and 23° C., of less than 30 cc/m²/24 h.

The above-mentioned objects, as well as other objects as will be realized by the skilled person in the light of the present disclosure, are achieved by the various aspects of the present disclosure.

The present invention is based on the understanding that very thin metal layers, typically having a thickness in the range of 20-600 nm, and more preferably in the range of 50-250 nm, formed by vacuum coating processes, such as physical vapor deposition (PVD) or chemical vapor deposition (CVD), can provide good oxygen and water vapor barrier properties, comparable to the barrier properties of thicker aluminum foils. As the thickness of the vacuum coating layer is typically at least an order of magnitude lower than the thickness of conventional foils, the metal content of the products can be dramatically reduced.

However, vacuum coating performed directly on the substrate to be vacuum coated, so called direct vacuum coating, has been found to be problematic for thicker, low-density paperboard base layers. Also, lamination of vacuum coated films to a paperboard base layer is often associated with curling of the web and/or pinhole formation or cracking of the thin and sensitive vacuum coating layers.

The present invention is based on the realization that at least some of these problems can be overcome by performing the lamination using a press nip, wherein the position of the press nip is adjustable in relation to the web surface, at least in a direction perpendicular to the laminated surfaces, during the lamination. In other words, the position of press nip may be adjusted in a direction perpendicular to the laminated surfaces during the lamination.

According to a first aspect illustrated herein, there is provided a method for manufacturing a paperboard based packaging laminate, said method comprising:
a) providing a paperboard base layer,
b) providing a vacuum coated film layer,
c) applying an adhesive composition to the paperboard base layer and/or the vacuum coated film layer,
d) laminating a surface of the paperboard base layer to a surface of the vacuum coated film layer using the adhesive composition in a press nip, such that the adhesive composition forms an adhesive tie layer between the paperboard base layer and the vacuum coated film layer, to form a laminate,
   wherein the position of the press nip is adjusted in a direction perpendicular to the laminated surfaces during the lamination to compensate for changes in curl in the formed laminate.

Paperboard generally refers to strong, thick paper or cardboard comprising cellulose fibers used for boxes and other types of packaging. Paperboard can either be bleached or unbleached, coated or uncoated, and produced in a variety of thicknesses, depending on the end use requirements. Paperboard may be a single ply material, or a multiply material comprised of two or more plies. A common type of multiply paperboard is comprised of a lower density mid-ply (also sometimes referred to as “bulk ply”) sandwiched between two higher density outer plies. The lower density mid-ply may typically have a density below 750 kg/m³, preferably below 700, below 650, below 600, below 550, below 500, below 450, below 400 or below 350 kg/m³. The higher density outer plies typically have a density at least 100 kg/m³ higher than the mid-ply, preferably at least 200 kg/m³ higher than the mid-ply.

A paperboard based packaging laminate is a packaging material formed mainly from paperboard base layer. The paperboard base layer can be made from pulp, including pulp from virgin fiber, e.g. mechanical, chemical and/or thermomechanical pulps. It can also be made from broke or recycled paper. In some embodiments, the paperboard base layer is a so-called duplex or triplex paperboard. In addition to the paperboard base layer, the paperboard based packaging laminate may comprise additional layers or coatings designed to improve the performance and/or appearance of the packaging laminate.

The paperboard based packaging laminate typically has a first outermost surface intended to serve as the outside surface, or print side, and a second outermost surface intended to serve as the inside surface of a packaging container. The side of the paperboard base layer comprising the vacuum coating layer is preferably intended to serve as the inside surface of a packaging container.

The paperboard based packaging laminate obtained by the inventive method can provide both excellent water vapor barrier properties and liquid barrier properties. Especially useful is the high water vapor barrier properties at high humidity and temperature enabled by the vacuum coated film layer. The term high humidity in the context of the present disclosure generally refers to a relative humidity (RH) of 50% or higher. The term high temperature in the context of the present disclosure generally refers to a temperature of 23° C. or higher. Water vapor barrier properties of the packaging laminates at high humidity and temperature are typically measured at a representative relative humidity (RH) of 50% and a temperature of 23° C. With the inventive method, paperboard based packaging laminates can be obtained, which have a water vapor transmission rate (WTR), measured according to the standard ASTM F1249-20 at 50% relative humidity and 23° C., of less than 30 cc/m²/24 h.

The inventive method is especially useful for manufacturing paperboard based packaging laminate comprising a thick, low-density paperboard base layer. The paperboard base layer used in the inventive method is typically a relatively thick paperboard, having a grammage of at least 100 g/m², preferably in the range of 100-1000 g/m². The density of the paperboard base layer is typically below 800 kg/m³. The bending resistance of the paperboard base layer as measured according to ISO2493 (L&W,) 15° in the machine direction may typically be above 80 mN.

The paperboard base layer may also be heavier. In some embodiments, the paperboard base layer has a grammage of at least 150 g/m², 200 g/m², 250 g/m², 300 g/m², 350 g/m², or 400 g/m². The grammage of the paperboard base layer is preferably below 1000 g/m², 800 g/m², or 600 g/m². Unless otherwise stated, the grammage is determined according to the standard ISO 536.

In some embodiments, the paperboard base layer has a density below 700 kg/m³, preferably below 600 kg/m³. Unless otherwise stated, the density is determined according to the standard ISO 534.

In some embodiments, the bending resistance of the paperboard base layer in the machine direction (MD) as measured according to ISO 2493 (L&W,) 15° is above 90 mN, preferably above 100 mN.

In some embodiments, the bending resistance of the paperboard base layer in the cross-machine (CD) direction as measured according to ISO 2493 (L&W,) 15° is above 40 mN, preferably above 45 mN.

In some embodiments, the paperboard base layer has a bending resistance index of at least 1.3, preferably at least 1.5, as measured according to ISO 2493-2. In some embodiments, the paperboard base layer has a bending resistance index of at least 1.7 as measured according to ISO 2493-2.

The paperboard base layer may be a single ply paperboard or a multiply paperboard. In some embodiments, the paperboard base layer is a multiply paperboard. In some embodiments the paperboard base layer is a multiply paperboard comprised of two or more plies. In some embodiments the paperboard base layer is a multiply paperboard comprised of three or more plies. In some embodiments the paperboard base layer is a multiply paperboard comprised of a lower density mid-ply sandwiched between two higher density outer plies.

In some embodiments, the paperboard base layer comprises a foam formed paperboard. In some embodiments, the paperboard base layer is a foam formed paperboard. In some embodiments wherein the paperboard base layer is a multiply paperboard, at least one of the plies, preferably a mid-ply, is foam formed.

The structure of the inventive paperboard based packaging laminate enables the use of a larger amount of recycled fibers in the paperboard base layer since the barrier structure hinders the migration of undesired contaminants, such as mineral oil based compounds. Thus, in some embodiments, the paperboard base layer comprises at least 5 wt % recycled fibers, preferably at least 10 wt % recycled fibers.

In some embodiments, the paperboard base layer further comprises a mineral coating layer on one or both of its main surfaces.

In some embodiments, the mineral coating layer comprises
50-95 wt % of a particulate mineral, and
5-50 wt % of a binder,
   based on the total dry weight of the mineral coating layer.

In some embodiments, the mineral coating layer comprises 65-95 wt % of a particulate mineral, and 5-35 wt % of a binder. In some embodiments, the mineral coating layer comprises 80-94 wt % of a particulate mineral, and 6-20 wt % of a binder. In some embodiments, the mineral coating layer comprises 86-94 wt % of a particulate mineral, and 6-14 wt % of a binder.

In some embodiments, the particulate mineral is selected from the group consisting of kaolin, calcium carbonate, bentonite, talc, and combinations thereof, preferably kaolin or calcium carbonate, and more preferably kaolin.

The binder may comprise a single binder or a combination of binders. The binder may preferably comprise a water-dispersible or water-soluble binder, or a combination thereof. In some embodiments, the water-dispersible binder comprises a latex binder. In some embodiments, the water-soluble binder comprises a starch or starch derivatives, PVOH or modified versions thereof, a cellulose derivate such as CMC, a protein, or seaweed. An advantage of using a water-soluble binder is that the laminate will be even more easy to recycle.

In some embodiments, the grammage of the mineral coating layer is in the range of 4-30 g/m², more preferably in the range of 6-14 g/m².

The mineral coating layer may preferably be applied in at least two different coating steps with drying of the coated film between the steps. The mineral coating layer may also be calendered, preferably in a soft calender or belt calender.

In some embodiments, the packaging laminate is further provided with a barrier coating layer for improving the gas barrier properties, particularly the oxygen barrier properties, of the laminate. The barrier coating layer is preferably arranged between the paperboard base layer and the vacuum coated film layer. In some embodiments the barrier coating layer is in direct contact with the base layer.

The barrier coating layer is preferably soluble in cold water or soluble in water after heating to a temperature below 100° C. for a given period of time. The water solubility of the barrier coating layer improves the separation of the vacuum coated film layer from the base layer during repulping.

In some embodiments, the barrier coating layer comprises a polymer selected from the group of polyvinyl alcohol (PVOH), a copolymer of ethylene and polyvinyl alcohol, starch, carboxymethylcellulose and combinations thereof. In some embodiments, the polymer of the barrier coating layer is PVOH.

The PVOH may for example have a degree of hydrolysis in the range of 80-99 mol %, preferably in the range of 85-98 mol %. The crystallinity of the PVOH is preferably less than 0.6, preferably less than 0.5, and more preferably less than 0.4 as determined by wide-angle x-ray scattering.

In some embodiments, the barrier coating layer comprises at least 50 wt % PVOH, preferably at least 70 wt % PVOH, based on the total dry weight of the barrier coating layer.

The PVOH may be an unmodified PVOH or a modified PVOH. The modified PVOH may preferably be an ethylene modified PVOH.

To minimize the risk of pinholes in the barrier coating layer, the barrier coating layer may preferably be applied in at least two different coating steps with drying of the coated film between the steps.

The barrier coating layer is preferably formed by means of a liquid film coating process, i.e. in the form of an aqueous solution or dispersion which, on application, is spread out to a thin, uniform layer on a substrate and thereafter dried. The barrier coating layer can be applied by contact or non-contact coating methods. Examples of useful coating methods include, but are not limited to rod coating, curtain coating, film press coating, cast coating, transfer coating, size press coating, flexographic coating, gate roll coating, twin roll HSM coating, blade coating, such as short dwell time blade coating, jet applicator coating, spray coating, gravure coating or reverse gravure coating.

In some embodiments, at least one barrier coating layer is applied in the form a foam. Foam coating is advantageous as it allows for film forming at higher solids content and lower water content compared to an unfoamed coating. The lower water content of a foam coating also reduces the problems with rewetting of the paperboard base layer. The foam may be formed using a polymeric or non-polymeric foaming agent. Examples of polymeric foaming agents include PVOH, hydrophobically modified starch, and hydrophobically modified ethyl hydroxyethyl cellulose.

In some embodiments, a cross-linking agent is added to the barrier coating layer. A cross-linking agent can improve water resistance and adhesion of the barrier coating layer. Suitable cross-linking agents include, but are not limited to, glyoxal, citric acid, glutaraldehyde. The concentration of the cross-linking agent may for example be 1-20 wt %, preferably 1-15 wt %, based on the barrier coating layer weight.

In some embodiments, the barrier coating layer further comprises water-insoluble particles in an amount of less than 30 wt %, based on the dry weight of the barrier coating layer. The term water-insoluble as used herein means that the particles are insoluble in water at 23° C. and pH 7-8. In some embodiments, the water-insoluble particles are microfibrillated cellulose (MFC) or cellulose nanocrystals. In a preferred embodiment, the barrier coating layer coating comprises 70-100 wt %

PVOH and 30-0 wt % MFC or cellulose nanocrystals. The MFC or cellulose nanocrystals provides reinforcement and improves mechanical properties of the PVOH.

In some embodiments, the coat weight of the barrier coating layer is in the range of 0.5-15 g/m², preferably in the range of 0.5-10 g/m², more preferably in the range of 1-8 g/m², and more preferably in the range of 2-6 g/m².

In some embodiments, the barrier coating layer also acts as the adhesive tie layer between the paperboard base layer and the vacuum coated film layer.

In some embodiments, the paperboard base layer is subjected to plasma treatment, corona treatment, flame treatment or steam treatment prior to the lamination.

The PPS (Parker Print-Surf) smoothness according to ISO 8791-4 of the mineral coating layer is preferably less than 5 μm, and more preferably in the range of 0.3-4 μm. The Cobb-Unger value (30s, bs) of the mineral coating layer is preferably less than 20 g/m², preferably in the range of 1-20 g/m², and more preferably in the range of 5-15 g/m², wherein the Cobb-Unger value is a measure of the oil absorption and measured by the SCAN-P 37:77 (30 seconds) method.

The paperboard base layer, before the lamination, typically has a high water vapor transmission rate (WVTR) value, i.e. poor water vapor transmission resistance. In some embodiments, the paperboard base layer has a water vapor transmission rate (WVTR), measured according to the standard ASTM F1249-20 at 50% relative humidity and 23° C., of above 100 g/m²/24 h, typically above 200 g/m²/24 h, above 300 g/m²/24 h, or above 1000 g/m²/24 h.

Onto the provided paperboard base layer, a vacuum coated film layer is laminated using an adhesive composition. A surface of the paperboard base layer is laminated to a surface of the vacuum coated film layer using the adhesive composition in a press nip, such that the adhesive composition forms an adhesive tie layer between the paperboard base layer and the vacuum coated film layer.

The vacuum coated film layer typically comprises a vacuum coating layer formed on a substrate film.

The term film as used herein refers generally to a thin continuous sheet formed material. The film may be a plastic film or a fiber-based film, preferably formed from highly refined fibrous material such as highly refined or microfibrillated cellulose. Depending on its composition, purpose and properties, the film can also be considered as a thin paper or even as a membrane.

In some embodiments, the substrate film is a plastic film, preferably a film formed from polyethylene (PE), polypropylene (PP), or polyethylene terephthalate (PET).

In some embodiments, the substrate film is a fiber-based film, preferably a cellulose-based film. When the substrate film is a fiber-based film, the film is preferably formed from highly refined fibrous material.

In some embodiments, the substrate film is a thin high-density paper such as a kraft paper, greaseproof paper, glassine paper, tracing paper, translucent paper, transparent paper, machine glazed paper or parchment paper. The thin high density-paper may preferably have a grammage in the range of 25-95 g/m² and a density above 800 kg/m³, more preferably above 900 kg/m³.

In a preferred embodiment, the substrate film is formed from microfibrillated cellulose (MFC).

In some embodiments, wherein the substrate film is a fiber-based film, the substrate film may be surface treated to improve the smoothness and decrease the porosity of the substrate surface and make the surface more suitable for vacuum coating. Possible surface treatments include, but are not limited to providing the surface with a smoothening precoat or mechanical smoothening, e.g. by calandering.

The surface treatment may for example include applying a precoat or primer layer to the substrate film. The precoat layer preferably acts to level out unevenness, and fill pores and pinholes present in the fibrous or porous substrate film. The surface treatment may also include subjecting the substrate surface to corona or plasma treatment in order to improve adhesion.

Calandering may include hard nip or soft nip calandering in one or several passes or nips. The mechanical smoothening can also be combined with a precoating step, performed before or after the calandering.

Thus, in some embodiments, the metallized film layer further comprises a precoat layer disposed between the substrate film and the vacuum coating layer.

In some embodiments, the precoat layer comprises a water-soluble polymer selected from the group consisting of a polyvinyl alcohol, a modified polyvinyl alcohol, a polysaccharide and a modified polysaccharide, or combinations thereof, preferably polyvinyl alcohol.

The PVOH may be a single type of PVOH, or it can comprise a mixture of two or more types of PVOH, differing e.g. in degree of hydrolysis or viscosity. The PVOH may for example have a degree of hydrolysis in the range of 80-99 mol %, preferably in the range of 85-99 mol %. Examples of useful products are, e.g., Kuraray Poval 4-98, Poval 6-98, Poval 10-98, Poval 15-99, Poval 20-98, Poval 30-98, or Poval 56-98 or mixtures of these. From the less hydrolysed grades, the Poval 4-88, Poval 6-88, Poval 8-88, Poval 18-88, Poval 22-88, or e.g. Poval 49-88 are preferred.

The modified polysaccharide may for example be a modified cellulose, such as carboxymethylcellulose (CMC) or hydroxypropyl cellulose (HPC), or a modified starch, such as a hydroxyalkylated starch, a cyanoethylated starch, a cationic or anionic starch, or a starch ether or a starch ester. Some preferred modified starches include hydroxypropylated starch, hydroxyethylated starch, dialdehyde starch and carboxymethylated starch.

In some embodiments, the precoat layer comprises up to 50 wt %, preferably in the range of 1-20 wt %, of micrifibrillated cellulose (MFC) or nanocrystalline celllose (NCC), based on dry weight.

In some embodiments, the precoat layer comprises up to 20 wt %, preferably in the range of 1-15 wt %, of a flaky phyllosilicate, graphene or a graphene oxide, or a mixture thereof, or a mixture thereof, based on dry weight.

In some embodiments, the basis weight of the precoat layer is in the range of 0.1-12 g/m², preferably in the range of 0.5-8 g/m², more preferably in the range of 1-6 g/m².

To minimize the risk of pinholes in the precoat layer, the precoat layer may preferably be applied in at least two different coating steps with drying of the coated film between the steps.

The precoat layer can be applied by contact or non-contact coating methods. For application on MFC layers, non-contact coating methods are typically preferred to minimize the risk of damage to the substrate during coating. Examples of useful coating methods include, but are not limited to rod coating, curtain coating, film press coating, cast coating, transfer coating, size press coating, flexographic coating, gate roll coating, twin roll HSM coating, blade coating, such as short dwell time blade coating, jet applicator coating, spray coating, gravure coating or reverse gravure coating. In some embodiments, the coating is applied in the form a foam. Foam coating is advantageous as it allows for film forming at higher solids content and lower water content compared to an unfoamed coating. The lower water content of a foam coating also reduces the problems with rewetting of the paperboard base layer.

The vacuum coating layer is formed on the substrate film. Vacuum coating refers to a family of processes used to deposit layers of metals, metal oxides and other inorganic and organic compositions, typically atom-by-atom or molecule-by-molecule, on a solid surface. Multiple layers of the same or different materials can be combined. The process can be further specified based on the vapor source; physical vapor deposition (PVD) uses a liquid or solid source and chemical vapor deposition (CVD) uses a chemical vapor.

The vacuum coating layer may be formed on one or both sides of the substrate film.

Vacuum coating typically results in very thin coatings. In some embodiments, the vacuum coating layer has a thickness in the range of 10-600 nm, preferably in the range of 10-250 nm, and more preferably in the range of 50-250 nm. This should be compared to conventional aluminum foils used in packaging laminates, which foils typically have thickness in the range of about 3-12 μm.

The vacuum coating layer may be inorganic or organic. In some embodiments, the vacuum coating layer comprises an inorganic vacuum coating layer, such as a metal, metal oxide, or ceramic vacuum coating layer. Vacuum coating of metals and metal oxides is often referred to as metallization.

In some embodiments, the vacuum coating layer comprises a metal or metal oxide selected from the group consisting of aluminum, magnesium, silicon, copper, aluminum oxides, magnesium oxides, silicon oxides, and combinations thereof, preferably aluminum or an aluminum oxide.

One preferred type of vacuum coating, often used for its barrier properties, in particular water vapour barrier properties, is an aluminum metal physical vapour deposition (PVD) coating. Such a coating, substantially consisting of aluminum metal, may typically have a thickness of from 50 to 250 nm, although a thickness even lower than 50 nm may also be useful, and even preferred in some embodiments. The typical thickness of the vacuum coating layer corresponds to less than 1% of the aluminum metal material typically present in an aluminum foil of conventional thickness for packaging, i.e. 6.3 μm. Thus, in some embodiments, the vacuum coating layer comprises aluminum.

The thickness of the vacuum coating layer may also be characterized by the optical density of the layer. In some embodiments the vacuum coating layer has an optical density above 1.8, preferably above 2.0, above 2.5, above 2.7, or above 3.0.

Aluminum oxide vacuum coating layers also known as AlOx coatings can provide similar barrier properties as aluminum metal coatings, but have the added advantage of thin AlOx coatings being transparent to visible light.

In some embodiments, the vacuum coating layer comprises an organic vacuum coating layer. The organic vacuum coating may for example be a vacuum coated carbon layer, such as a diamond-like carbon (DLC) layer formed from carbon or organic compounds.

In some embodiments, the vacuum coating layer is applied to the substrate film by a transfer coating process. Transfer coating, also commonly referred to as transfer metallization when the coating comprises a metal, generally involves transferring a thin vacuum coating layer from a transfer coating substrate to a substrate film to be coated, using an adhesive layer applied between the vacuum coating layer and the substrate film to be coated.

The transfer coating substrate comprises a vacuum coating layer and a backing layer, and the vacuum coating layer and the backing layer are separated by a release layer having low adhesion to the vacuum coating layer and/or the backing layer, such that the vacuum coating layer can be readily separated from the backing layer.

For the transfer coating process, an adhesive layer is applied on the substrate film or on the vacuum coating layer or on both layers. The vacuum coating layer is transferred to the substrate film using the adhesive layer applied on the substrate film and/or the vacuum coating layer. The vacuum coating layer is contacted and adhered to the substrate film using the adhesive layer applied on the substrate film and/or the vacuum coating layer. Once the vacuum coating layer has adhered to the substrate film, the backing layer removed from the vacuum coating layer, leaving the adhered vacuum coating layer, and optionally the release layer, on the substrate film. Possible additional layers added between the release layer and the vacuum coating layer, and/or on top of the vacuum coating layer will also remain on the substrate film.

The vacuum coated film layer may further comprise a protective layer applied on top of the vacuum coating layer for protecting the thin and sensitive vacuum coating layer during manufacture, handling and transport prior to the lamination process.

An adhesive composition is applied to the paperboard base layer and/or the vacuum coated film layer, and the paperboard base layer is laminated to the vacuum coated film layer using the adhesive composition in a press nip, such that the adhesive composition forms an adhesive tie layer between the paperboard base layer and the vacuum coated film layer. The adhesive composition may be applied directly to the paperboard base layer surface, or it may first be applied to the vacuum coated film layer, and then applied to the paperboard base layer together with the vacuum coated film layer, or both. An advantage of applying the adhesive composition to both surfaces is that the wetting of the surfaces can be reduced.

The adhesive composition may be any composition providing adhesion between the laminated layers. Typically, the adhesive composition comprises an adhesive polymer. The adhesive composition may also comprise two or more adhesive polymers. The adhesive composition may be comprised entirely of the one or more adhesive polymers, or it may also further comprise other additives for facilitating the coating process or improving the properties of the adhesive tie layer. In some embodiments, the adhesive composition comprises at least 50 wt % of an adhesive polymer or mixture of adhesive polymers based on dry weight.

The adhesive composition may for example be applied to the paperboard base layer and/or the vacuum coated film layer by extrusion coating or by liquid coating in the form of a dispersion, latex or solution of the of the adhesive polymer in an aqueous carrier.

In some embodiments, the adhesive composition is applied by extrusion coating.

Extrusion coating of thermoplastic polymers is useful since very thin and homogenous adhesive films can be conveniently formed. In some embodiments, the adhesive composition comprises one or more adhesive polymers selected from the group consisting of polyolefins, polyurethanes, and acrylic copolymers. In some embodiments, the adhesive composition comprises a polyolefin, preferably polyethylene (PE).

The grammage of the extrusion coated adhesive tie layer may be in the range of 3-20 g/m² based on dry weight.

The adhesive composition is preferably applied by means of a liquid film coating process, i.e. in the form of a solution or dispersion which, on application, is spread out to a thin, uniform layer on the substrate and thereafter dried. The liquid phase of the solution or dispersion is preferably water or an aqueous solution, but organic solvents or mixtures of water or aqueous solutions and organic solvents may also be used. The one or more adhesive polymers may be present in the solution or dispersion in dissolved form or in the form of polymer particles, such as a latex. The adhesive composition can be applied by contact or non-contact coating methods. Examples of useful coating methods include, but are not limited to rod coating, curtain coating, film press coating, cast coating, transfer coating, size press coating, flexographic coating, gate roll coating, twin roll HSM coating, blade coating, such as short dwell time blade coating, jet applicator coating, spray coating, gravure coating or reverse gravure coating.

In some embodiments, the adhesive composition is applied in the form of a dispersion, latex or solution of the of the adhesive polymer in an aqueous carrier.

In some embodiments, the dispersion, latex or solution comprises polyvinyl alcohol (PVOH), styrene-acrylate (SA) latex, styrene-butadiene (SB) latex, starch, carboxymethyl cellulose (CMC), or a polyolefin.

The grammage of the adhesive tie layer applied in the form of a dispersion, latex or solution may be in the range of 0.5-8 g/m² based on dry weight. In some embodiments, the dispersion, latex or solution is applied as a single layer at a grammage in the range of 0.5-8 g/m² based on dry weight in one application step. To minimize the risk of pinholes in the adhesive tie layer, the adhesive composition may preferably be applied in at least two different coating steps with drying of the coated adhesive film between the steps. In some embodiments, the dispersion, latex or solution is applied in two or more consecutive application steps, e.g. 2+2 g/m² or 1+3 g/m² or 2+4 g/m². Application in two or more consecutive application steps also enables less adhesive penetration into the paperboard base layer since the first adhesive layer act as a first coating and closes the surface

In some embodiments, the adhesive composition comprises at least 50 wt % of a water-soluble polymer or mixture of water-soluble polymers based on dry weight. The water-soluble polymer of the adhesive composition is soluble in cold water or soluble in hot water, e.g. at a temperature below 100° C. or even above 100° C., for a given period of time. The water-soluble polymer in addition to acting as an adhesive for the laminate, also facilitates separation of the laminated layers during repulping. In some embodiments, the water-soluble polymer is selected from the group consisting of a polyvinyl alcohol (PVOH), a carboxymethyl cellulose (CMC), a starch, an alginate, and a hemicellulose, preferably a PVOH.

In some embodiments, the dispersion, latex or solution has a solid content in the range of 10-70 wt %, preferably in the range of 15-65 wt %, at the point of application. A solid content of at least 10 wt % and more preferably at least 15 wt % at the point of application enables fast immobilization of the adhesive and good concentration of the adhesive composition at the surface. With lower solids too much water is applied which can cause swelling of the substrate and problems with dimensional stability and curing.

In some embodiments, the dispersion, latex or solution has a viscosity of in the range of 100-4000 mPas, preferably in the range of 300-2500 mPas, as determined using a Brookfield viscosimeter, such as a Brookfield DVNext rheometer, at rotational speed of 100 rpm. This viscosity ensures good runnability using rod or gravure coating methods.

In some embodiments, the dispersion, latex or solution has an ÅAGWR water retention value (Åbo Akademi Water retention value) below 250 g/m², preferably in the range of 30-150 g/m², as determined according to TAPPI standard T701 pm-01. This water retention ensures good runnability using rod or gravure coating methods, while also minimizing penetration of the coating composition into the base layer and enabling good distribution of the adhesive on the base layer surface.

In some embodiments, at least one adhesive composition is applied in the form of a foam. Foam coating is advantageous as it allows for film forming at higher solids content and lower water content compared to a non-foamed coating. The lower water content of a foam coating also reduces the problems with rewetting of the paperboard base layer. The foam may be formed using a polymeric or non-polymeric foaming agent. Examples of polymeric foaming agents include PVOH, hydrophobically modified starch, and hydrophobically modified ethyl hydroxyethyl cellulose.

In some embodiments, the adhesive composition further comprises a crosslinking agent capable of crosslinking the water-soluble polymer. Crosslinking improves the water vapor barrier properties of the adhesive layer. Suitable crosslinking agents include, but are not limited to polyfunctional organic acids or aldehydes, such as citric acid, glyoxal, zirconium carbonates, and glutaraldehyde. In some embodiments, the crosslinking agent is an organic acid, and more preferably citric acid. The concentration of the crosslinking agent may for example be 1-20 wt %, preferably 1-15 wt %, based on the dry weight of the adhesive layer.

In some embodiments, the adhesive composition comprises PVOH and citric acid.

Crosslinking of the PVOH with citric acid improves the water vapor barrier properties of the adhesive tie layer.

In some embodiments, the adhesive composition further comprises up to 50 wt % of microfibrillated cellulose (MFC), nanocrystalline cellulose, a chemically modified cellulose derivative such as sodium carboxymethyl cellulose, hydroxypropyl cellulose, ethyl hydroxyethyl cellulose, cellulose acetate, hydroxyethyl cellulose, a hemicellulose, or a combination thereof, based on dry weight.

In some embodiments, the adhesive tie layer also acts as a barrier coating layer.

In some embodiments, the composition of the adhesive tie layer may be selected as described above with reference to the barrier coating layer.

The surface of the paperboard base layer is laminated to a surface of the vacuum coated film layer using the adhesive composition in a press nip, such that the adhesive composition forms an adhesive tie layer between the paperboard base layer and the vacuum coated film layer, to form a laminate.

The press nip is formed by a press roll configured to apply pressure to the moving laminate. The press roll may typically be made of steel, optionally coated or surface treated steel. The radius of the press roll is preferably at least 10 cm. In some embodiments, the radius of the press roll is at least 20 cm, at least 30 cm, or at least 40 cm. In some embodiments, the press nip is formed between a press roll and a counter roll or belt. The counter roll may also be made of steel, optionally coated or surface treated steel, or it can be made of a polymeric material such as plastic or rubber. The counter belt may be made of steel, optionally coated or surface treated steel, or it can be made of a polymeric material such as plastic or rubber. The paperboard base layer and vacuum coated film layer and the adhesive composition disposed between them are fed into the press nip and subjected to pressure between the press roll and the counter roll or belt. In some embodiments, guide rolls are further provided before and/or after the press nip. The guide rolls can be used for guiding the paperboard base layer, the vacuum coated film layer, and/or the formed laminate to a desired path. The guide rolls can also be used for adjusting the angle between the paperboard base layer and the vacuum coated film as they are fed to the press nip.

Since the nip will be short in a conventional roll press nip, wherein the nip is formed between the press roll and a counter roll, the press load of the nip may typically not be increased over a certain limit without crushing and causing damage to the paperboard base layer. Also, the dwell time suffers due to the high machine speeds in modern paper machines. Therefore, in some embodiments the press nip is an extended nip, i.e. a nip having a point of contact between the press roll and the laminate which is extended in the machine direction. This extends the time for which the laminate is subjected to pressure in the nip and may reduce the press load and/or temperature required to achieve the same lamination effect as in a shorter nip. In some embodiments, the extended nip is a shoe nip. In some embodiments, the extended nip, or shoe nip, has a nip contact length of at least 10 mm, preferably at least 50 mm, and more preferably at least 100 mm, such as in the range of 100 mm to 1000 mm.

In some embodiments, the press nip has a press load in the range of 0.5-150 kN/m, preferably in the range of 1-100 KN/m, more preferably in the range of 2-75 KN/m or in the range 3-50 kN/m. The press load is high enough to achieve sufficient contact between the paperboard base layer and vacuum coated film layer and the adhesive composition disposed between them, yet not so high that it crushes and causes damage to the paperboard base layer. In preferred embodiments, at least 80% of the average thickness of the paperboard base layer is retained after the press nip. Preferably at least 85%, more preferably at least 90% and even more preferably at least 93% of the average thickness of the paperboard base layer is retained after the press nip. The press load also enables the adhesive composition to solidify more evenly between the paperboard base layer and the vacuum coated film layer rather than becoming pressed into the paperboard base layer.

The press roll and/or the counter roll or belt may be heated in order to heat the laminate in the nip. Heating of the laminate can improve contact between the paperboard base layer and vacuum coated film layer and the adhesive composition disposed between them and may also accelerate drying and/or curing of the adhesive composition. In some embodiments, the press roll and/or the counter roll or belt is heated to a temperature in the range of 40-250° C., preferably to a temperature in the range of 70-250° C.

Application of the adhesive composition to the paperboard base layer during the lamination process may cause curling of the paperboard base layer as well as curling of the finished laminate. Curling of the base layer and laminate may also be exacerbated as the process proceeds, since the inherent curl in the paperboard base layer fed to the lamination step will increase as the paperboard reel is consumed and the diameter of the reel becomes smaller.

The present inventors have found that the curl in the finished laminate may advantageously be reduced by adjusting the position of the press nip in a direction perpendicular to the laminated surfaces during the lamination.

Thus, in some embodiments of the method of the present invention, the position of the press nip is adjustable in a direction perpendicular to the laminated surfaces during the lamination to compensate for changes in curl in the formed laminate.

In some embodiments of the inventive method, the position of the press nip is adjusted in a direction perpendicular to the laminated surfaces during the lamination to compensate for changes in curl in the formed laminate.

In some embodiments of the inventive method, the curl is reduced by adjusting the press nip in a direction perpendicular to the laminated surfaces towards the paperboard base layer side of the laminate. Adjusting the press nip in a direction towards the paperboard base layer side of the laminate will result in a bend or curve in the path of the web, wherein the paperboard base layer will be on the outside and the vacuum coated film layer will be on the inside of the bend or curve.

In some embodiments of the inventive method, the curl is reduced by adjusting the press nip in a direction perpendicular to the laminated surfaces towards the vacuum coated film layer side of the laminate. Adjusting the press nip in a direction towards the vacuum coated film layer side of the laminate will result in a bend or curve in the path of the web, wherein the vacuum coated film layer will be on the outside and the paperboard base layer will be on the inside of the bend or curve.

The present inventors have further found that the angle between the paperboard base layer and the vacuum coated film as they are fed to the press nip is important in order to avoid cracking of the vacuum coating of the vacuum coated film layer. The angle between the paperboard base layer and the vacuum coated film may increase as the lamination process proceeds, since the inherent curl in the paperboard base layer fed to the lamination step will increase as the paperboard reel is consumed and the diameter of the reel becomes smaller.

In some embodiments, the position of the press nip is adjustable in the machine direction during the lamination to compensate for changes in the angle between the paperboard base layer and the vacuum coated film at the press nip. Thus, in some embodiments the position of the press nip is adjustable both in a direction perpendicular to the laminated surfaces and in the machine direction during the lamination process.

In some embodiments, the position of the press nip is adjusted in the machine direction during the lamination to compensate for changes in the angle between the paperboard base layer and the vacuum coated film at the press nip. Thus, in some embodiments the position of the press nip is adjusted both in a direction perpendicular to the laminated surfaces and in the machine direction during the lamination process.

In some embodiments, the angle between the paperboard base layer and the vacuum coated film at the press nip is kept below 50°, preferably below 45°.

In some embodiments, the positions of the press roll and/or the counter roll or belt are adjustable independently of the other. In some embodiments, one of the press roll and the counter roll or belt is adjustable in a direction perpendicular to the laminated surfaces and in the machine direction. In some embodiments, the press roll and/or the counter roll or belt are both adjustable in a direction perpendicular to the laminated surfaces and in the machine direction. In some embodiments, one of the press roll and the counter roll or belt is adjustable in a direction perpendicular to the laminated surfaces, and the other of the press roll and the counter roll or belt is adjustable in the machine direction. In some embodiments, one of the press roll and the counter roll or belt is adjustable in a direction perpendicular to the laminated surfaces and in the machine direction, and the other of the press roll and the counter roll or belt is adjustable only in a direction perpendicular to the laminated surfaces or in the machine direction. Embodiments, wherein the positions of the press roll and/or the counter roll or belt are adjustable independently of the other allow for the press nip to be tilted. In embodiments wherein the counter roll or belt is a belt or a shoe, the belt or shoe can be tilted and the press roll adjusted accordingly.

In some embodiments, the positions of the press roll and/or the counter roll or belt are adjusted independently of the other. In some embodiments, one of the press roll and the counter roll or belt is adjusted in a direction perpendicular to the laminated surfaces and in the machine direction. In some embodiments, the press roll and/or the counter roll or belt are both adjusted in a direction perpendicular to the laminated surfaces and in the machine direction. In some embodiments, one of the press roll and the counter roll or belt is adjusted in a direction perpendicular to the laminated surfaces, and the other of the press roll and the counter roll or belt is adjusted in the machine direction. In some embodiments, one of the press roll and the counter roll or belt is adjusted in a direction perpendicular to the laminated surfaces and in the machine direction, and the other of the press roll and the counter roll or belt is adjusted only in a direction perpendicular to the laminated surfaces or in the machine direction. Embodiments, wherein the positions of the press roll and/or the counter roll or belt are adjusted independently of the other allow for the press nip to be tilted. In embodiments wherein the counter roll or belt is a belt or a shoe, the belt or shoe can be tilted and the press roll adjusted accordingly.

In some embodiments, the press nip is tilted. This means that the position of the press roll and/or the counter roll is adjusted in relation to the other such that the tangential plane at the point of contact between the rolls becomes tilted. Tilting the press nip during the lamination can compensate for changes in curl in the formed laminate. Tilting the press nip can be used to increase the time of contact between the paperboard base layer, the vacuum coated film layer, and/or the formed laminate, and the press roll or the counter roll respectively. This may for example be useful for increasing the time of contact between the laminate and a heated press roll.

The present inventors have further found that it is important to avoid any sharp turns in the web path during the lamination process in order to avoid cracking of the vacuum coating of the vacuum coated film layer. It is especially important to avoid any sharp turns in the web path following lamination of a vacuum coated film layer to a thick paperboard, having a grammage of at least 100 g/m² and a density below 800 kg/m3 since the stress on the vacuum coating in such laminates when subjected to sharp turns may be high. Thus, in some embodiments, the paperboard base layer, the vacuum coated film, and the obtained laminate are not subjected to a radius of curvature below 10 cm, preferably not below 20 cm, below 30 cm or below 40 cm. In some embodiments, the obtained laminate is not subjected to a radius of curvature below 10 cm, preferably not below 20 cm, below 30 cm or below 40 cm.

The paperboard based packaging laminate may further be provided with a polymeric sealing layer on one side or on both sides. The polymeric sealing layers provide heat sealing capability to the paperboard based packaging laminate surface, and may additionally provide improved liquid barrier properties and mechanical protection. The polymeric sealing layers may for example be applied by extrusion coating, film lamination or dispersion coating.

In some embodiments, the method further comprises the step:
e) applying at least one polymeric sealing layer to at least one side of the laminate.

In some embodiments, the method comprises the step:
e) applying at least one polymeric sealing layer to both sides of the laminate.

The polymeric sealing layers may comprise any of the thermoplastic polymers commonly used in heat-sealable layers in paperboard based packaging laminates in general or polymers used in liquid or food packaging board in particular.

Examples include polyethylene (PE), polypropylene (PP), polyhydroxyalkanoates (PHA), polylactic acid (PLA), polyglycolic acid (PGA), polybutylene terephthalate (PBT), starch and cellulose. In some embodiments, the polymeric sealing layer comprises a polyolefin layer, preferably a polyethylene layer. Polyethylenes, especially low density polyethylene (LDPE) and high density polyethylene (HDPE), are the most common and versatile polymers used in liquid or food packaging board. The polymers used are preferably manufactured from renewable materials.

In some embodiments, the polymeric sealing layers are formed by extrusion coating of the polymer onto a surface of the paperboard base layer or the obtained laminate. Extrusion coating is a process by which a molten plastic material is applied to a substrate to form a very thin, smooth and uniform layer. The coating can be formed by the extruded plastic itself, or the molten plastic can be used as an adhesive to laminate a solid plastic film onto the substrate.

The basis weight of each of the polymeric sealing layers is preferably less than 50 g/m². In order to achieve a continuous and substantially defect free film, a basis weight of the polymeric sealing layer of at least 8 g/m², preferably at least 12 g/m² is typically required. In some embodiments, the basis weight of the polymeric sealing layer is in the range of 8-50 g/m², preferably in the range of 12-50 g/m².

In a more specific embodiment, the paperboard based packaging laminate comprises a paperboard base layer, PVOH as the adhesive composition, and a metallized greaseproof paper as the vacuum coated film layer, and optionally a polyethylene layer as the polymeric sealing layer disposed on one or both sides of the laminate.

In some embodiments, the obtained paperboard based packaging laminate has an oxygen transmission rate (OTR), measured according to the standard ASTM F1927-20 at 50% relative humidity and 23° C., of less than 30 cc/m²/24 h, preferably less than 20 cc/m²/24 h, more preferably less than 10 cc/m²/24 h, and most preferably less than 5 cc/m²/24 h.

The obtained paperboard based packaging laminate has a significantly improved resistance to water vapor. In some embodiments, the obtained paperboard based packaging laminate has a water vapor transmission rate (WVTR), measured according to the standard ASTM F1249-20 at 50% relative humidity and 23° C., of less than 30 g/m²/24 h, preferably less than 20 g/m²/24 h, more preferably less than 10 g/m²/24 h, and most preferably less than 5 g/m²/24 h. This makes the inventive packaging laminate an interesting and viable alternative to conventional materials using aluminum foil layers.

Additionally, the inventive paperboard based packaging laminate can provide an alternative to conventional materials using aluminum foil layers, which can more readily be repulped and recycled. The adhesive tie layer of the inventive paperboard based packaging laminate preferably comprises at least 50 wt % of a water-soluble polymer based on dry weight. A water-soluble polymer arranged between and in contact with the paperboard base layer and the vacuum coated film layer has been found to allow for effective separation of the vacuum coating layer from the paperboard base layer during repulping. In some embodiments, the paperboard based packaging laminate has a reject rate according to PTS RH 021/97 of less than 30%, preferably less than 20%, more preferably less than 10%.

According to a second aspect illustrated herein, there is provided a method for manufacturing a container, particularly a liquid or food packaging container, said method comprising:
a) manufacturing a paperboard based packaging laminate as described with reference to the first aspect; and
b) converting the paperboard based packaging laminate into a container.

In some embodiments, the vacuum coating layer faces the inside of the container.

### BRIEF DESCRIPTION OF THE DRAWINGS

FIG. 1 is a schematic representation of the lamination process.

FIG. 2 is a schematic representation of the lamination process, wherein the press nip is adjusted in a direction perpendicular to the laminated surfaces.

FIG. 3 is a schematic representation of the lamination process, wherein the press nip is adjusted in the machine direction.

FIG. 4 is a schematic representation of the lamination process, wherein the press nip is tilted.

### DETAILED DESCRIPTION OF PREFERRED EMBODIMENTS

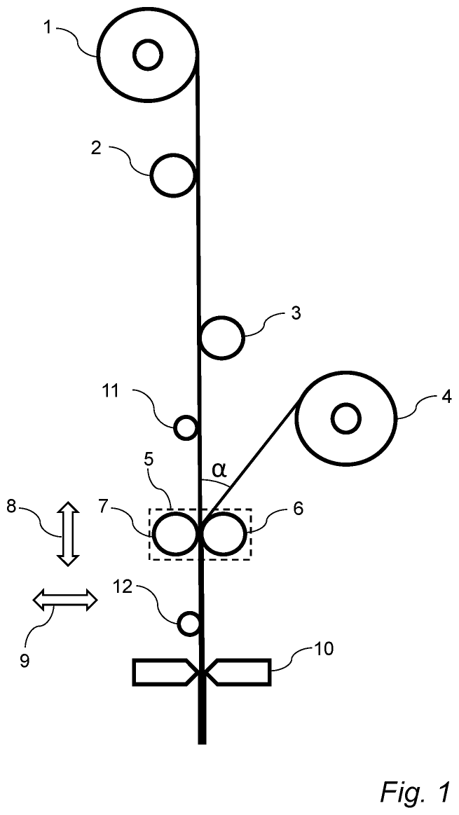

With reference to FIG. 1, a paperboard base layer is provided from the paperboard reel (1). A dispersion coating is applied to a first surface of the paperboard base layer in a first coating station (2). A water-based adhesive composition comprising polyvinyl alcohol (PVOH) is applied to the barrier coating in a second coating station (3). A vacuum coated film layer is provided from the vacuum coated film reel (4). The vacuum coated film layer is laminated to the adhesive coated surface of the paperboard base layer in a press nip (5) formed between a press roll (6) and a counter roll (7). The position of the press nip is gradually adjusted in a direction (8) perpendicular to the laminated surfaces towards the paperboard base layer side of the laminate during the lamination process. Adjusting the press nip in a direction towards the paperboard base layer side of the laminate will result in a bend or curve in the path of the web, wherein the paperboard base layer will be on the outside and the vacuum coated film layer will be on the inside of the bend or curve. Optionally, the position of the press nip is also gradually adjusted in the machine direction (9) during the lamination to compensate for the increase in the angle (a) between the paperboard base layer and the vacuum coated film at the press nip. The laminate is then provided with polymeric sealing layers on both sides by extrusion coating of polyethylene in an extrusion station (10). Guide rolls (11, 12) guide the paperboard base layer and the formed laminate to the desired path. The guide roll (11) can also be used for adjusting the angle between the paperboard base layer and the vacuum coated film as they are fed to the press nip. Adjustment of the press nip can be controlled online by measuring suitable parameters, e.g. moisture content or curl, in the paperboard base layer, the vacuum coated film layer, and/or the formed laminate and automatically, preferably using a CPU and a suitable algorithm, adjusting the press nip to compensate for changes in the measured parameters.

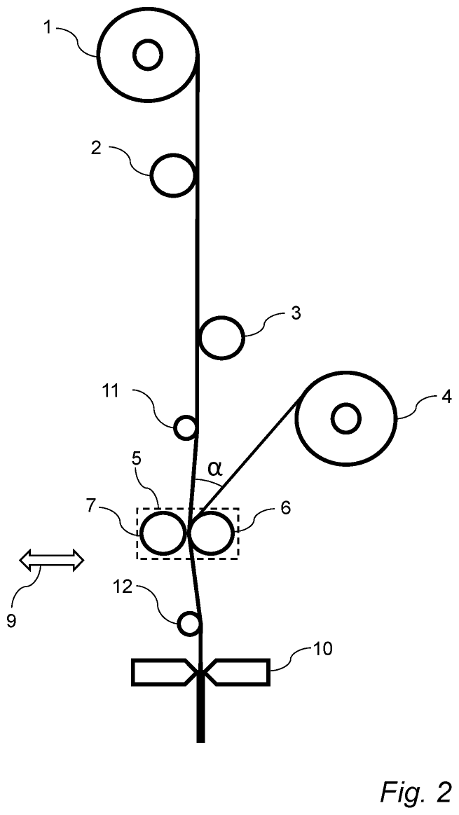

FIG. 2 depicts a process as described with reference to FIG. 1, but where the position of the press nip (5) is adjusted in a direction perpendicular to the laminated surfaces.

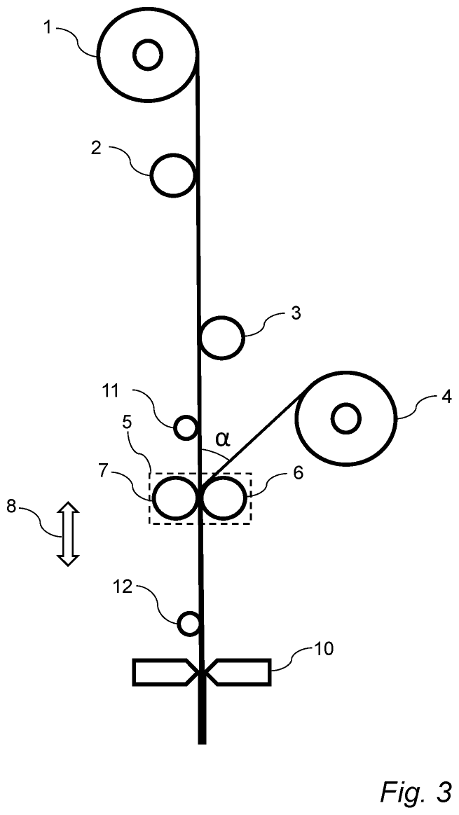

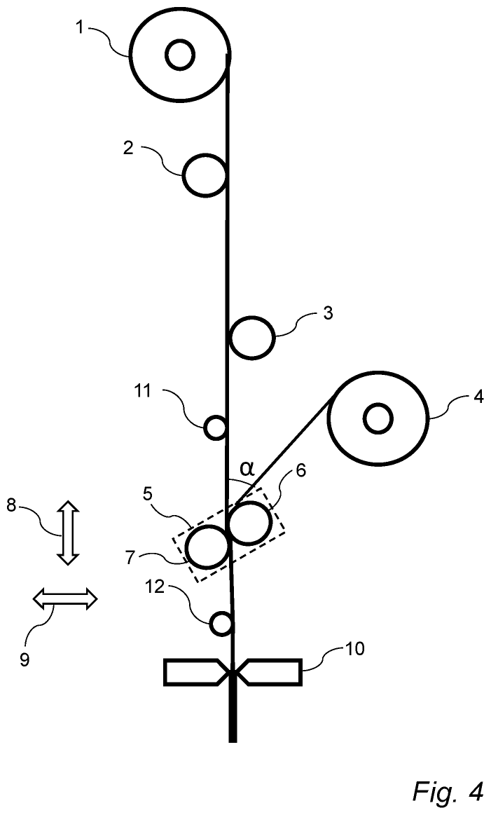

In FIG. 3 depicts a process as described with reference to FIG. 1, but where the position of the press nip (5) is adjusted in the machine direction. In FIG. 4 depicts a process as described with reference to FIG. 1, but where the position of the press nip (5) is adjusted in a direction perpendicular to the laminated surfaces and the press nip is tilted. This means that the position of the press roll and/or the counter roll is adjusted in relation to the other such that the tangential plane at the point of contact between the rolls becomes tilted.

Generally, while the products, polymers, materials, layers and processes are described in terms of “comprising” various components or steps, the products, polymers, materials, layers and processes can also “consist essentially of” or “consist of” the various components and steps.

While the invention has been described with reference to various exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method for manufacturing a paperboard based packaging laminate, said method comprising:
a) providing a paperboard base layer,
b) providing a vacuum coated film layer,
c) applying an adhesive composition to the paperboard base layer, or the vacuum coated film layer, or both,
d) laminating a surface of the paperboard base layer to a surface of the vacuum coated film layer using the adhesive composition in a press nip, such that the adhesive composition forms an adhesive tie layer between the paperboard base layer and the vacuum coated film layer, to form a laminate,
wherein a position of the press nip is adjusted in a direction perpendicular to the laminated surfaces during the lamination to compensate for changes in a curl in the laminate.

2. The method according to claim 1, wherein the position of the press nip is adjusted in a machine direction during the lamination to compensate for changes in an angle between the paperboard base layer and the vacuum coated film layer at the press nip.

3. The method according to claim 1, wherein an angle between the paperboard base layer and the vacuum coated film layer at the press nip is kept below 50°, preferably below 45°.

4. The method according to claim 1, wherein the press nip is formed between a press roll and a counter roll or belt.

5. The method according to claim 1, wherein the press nip is an extended nip, preferably a shoe nip.

6. The method according to claim 1, wherein the press nip has a press load in a range of 0.5-150 kN/m.

7. The method according to claim 4, wherein the press roll, or the counter roll, or the belt, or any combination thereof is heated to a temperature in a range of 40-250° C.

8. The method according to claim 1, wherein the paperboard base layer has a grammage in a range of 100-1000 g/m².

9. The method according to claim 1, wherein the paperboard base layer has a density below 800 kg/m³.

10. The method according to claim 1, wherein the paperboard base layer has a bending resistance in a machine direction as measured according to ISO 2493 (L&W,) 15° above 80 mN.

11. The method according to claim 1, wherein the paperboard base layer has a bending resistance in a cross-machine direction as measured according to ISO 2493 (L&W,) 15° above 40 mN.

12. The method according to claim 1, wherein the paperboard base layer is a multiply paperboard.

13. The method according to claim 1, wherein the paperboard base layer comprises a foam formed paperboard.

14. The method according to claim 1, wherein the vacuum coated film layer comprises a vacuum coating layer formed on a substrate film.

15. The method according to claim 14, wherein the substrate film is a plastic film.

16. The method according to claim 14, wherein the substrate film is a fiber-based film.

17. The method according to claim 14, wherein the vacuum coating layer comprises an inorganic vacuum coating layer.

18. The method according to claim 14, wherein the vacuum coating layer comprises an organic vacuum coating layer.

19. The method according to claim 14, wherein the vacuum coating layer has a thickness in the range of 10-600 nm, preferably in the range of 10-250 nm.

20. The method according to claim 1, wherein the adhesive composition comprises an adhesive polymer.

21. The method according to claim 1, wherein the adhesive composition is applied by extrusion coating.

22. The method according to claim 21, wherein the adhesive composition comprises a polyolefin.

23. The method according to claim 1, wherein the adhesive composition is applied as a dispersion, latex or solution of an adhesive polymer in an aqueous carrier.

24. The method according to claim 23, wherein the dispersion, latex or solution comprises polyvinyl alcohol (PVOH), styrene-acrylate (SA) latex, styrene-butadiene (SB) latex, starch, carboxymethyl cellulose (CMC), or a polyolefin.

25. The method according to claim 23, wherein the dispersion, latex or solution has a solid content in a range of 10-70 wt %, at a time of applying.

26. The method according to claim 1, further comprising the step:
e) applying at least one polymeric sealing layer to at least one side of the laminate.

27. The method according to claim 1, comprising the step:
e) applying at least one polymeric sealing layer to both sides of the laminate.

28. The method according to claim 26, wherein the polymeric sealing layer comprises a polyolefin layer.

29. The method according to claim 1, wherein the laminate has an oxygen transmission rate (OTR), measured according to standard ASTM F1927-20 at 50% relative humidity and 23° C., of less than 30 cc/m²/24 h.

30. The method according to claim 1, wherein the laminate has a water vapor transmission rate (WVTR), measured according to standard ASTM F1249-20 at 50% relative humidity and 23° C., of less than 30 g/m²/24 h.

31. A method for manufacturing a container, said method comprising:
a) manufacturing the laminate according to claim 1; and
b) converting the laminate into a container.

32. The method according to claim 31, wherein the vacuum coating layer faces an inside of the container.
